(19) United States
(12) Patent Application Publication
(10) Pub. No.: US 2010/0175912 A1
(43) Pub. Date: Jul. 15, 2010

(54) IC PACKAGE HAVING COLORED PATTERN

(76) Inventor: Juei-Tao SHIH, Taipei County (TW)

Correspondence Address: Muncy, Geissler, Olds & Lowe, PLLC, 4000 Legato Road, Suite 310, FAIRFAX, VA, 22033, US

(21) Appl. No.: 12/425,980

(22) Filed: Apr. 17, 2009

(30) Foreign Application Priority Data
Jan. 15, 2009 (TW) 98200754

(51) Int. Cl. H05K 1/00

(52) U.S. Cl. 174/250

(57) ABSTRACT

An IC package having a colored pattern includes a substrate, a chip electrically connected with the substrate, an insulating cover layer covering the chip, and a colored-pattern layer disposed on the insulating cover layer by ink jet printing or an alternative.

### BACKGROUND OF THE INVENTION

1. Field of the Invention

The present invention relates generally to IC packages, and more particularly, to an IC package having a colored pattern.

2. Description of the Related Art

A conventional IC package usually includes an insulating cover layer located at the outmost side thereof. To date, the insulating cover layer shows such color of the material that it is made of or is at most marked with such name of the manufacturer or such model number that the IC package is too lifeless to be sold as a single memory card in the market.

### SUMMARY OF THE INVENTION

The primary objective of the present invention is to provide an IC package, which includes a colored pattern disposed on at least one surface thereof.

The foregoing objective of the present invention is attained by the IC package, which is composed of a substrate, a chip electrically connected with the substrate, an insulating cover layer covering the chip, and a colored-pattern layer disposed on the insulating cover layer by ink jet printing.

### BRIEF DESCRIPTION OF THE DRAWINGS

FIG. 1 is a perspective view of a preferred embodiment of the present invention.

FIG. 2 is a sectional view taken from a line 2-2 indicated in FIG. 1.

FIG. 3 illustrates that the colored pattern of the preferred embodiment of the present invention is produced by ink jet printing.

### DETAILED DESCRIPTION OF PREFERRED EMBODIMENTS

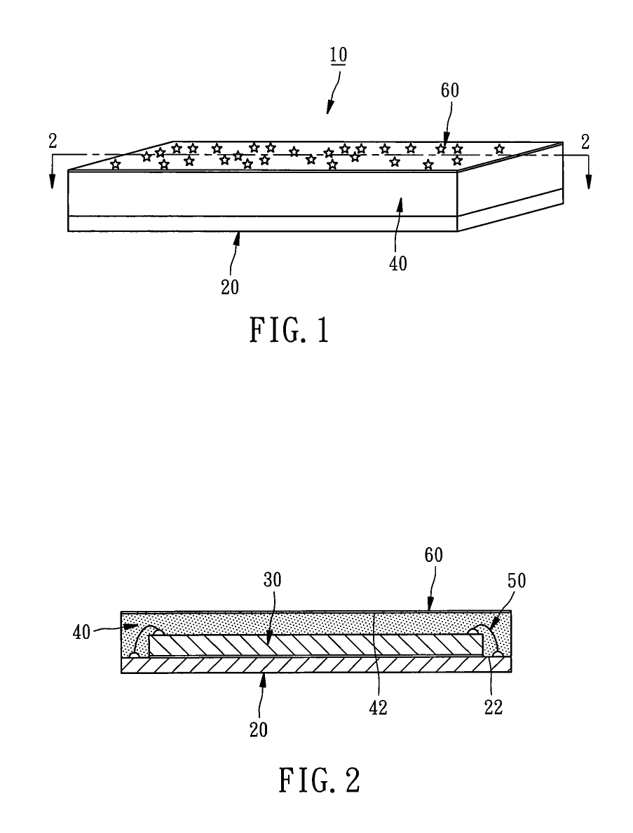

Referring to FIGS. 1-3, an IC package 10 having a colored pattern in accordance with a preferred embodiment of the present invention is rectangular or other shape and composed of a substrate 20, a chip 30, and an insulating cover layer 40. The substrate 20 includes a working surface 22. The chip 30 includes a bottom side attached to the working surface 22 by an insulative adhesive. The chip 30 includes a top side electrically connected with the working surface 22 by lead wires 50. The insulating cover layer 40 is made of plastic or resin, like epoxy, silicon gel, or acrylic, covering the chip 30 and the lead wires 50 by molding.

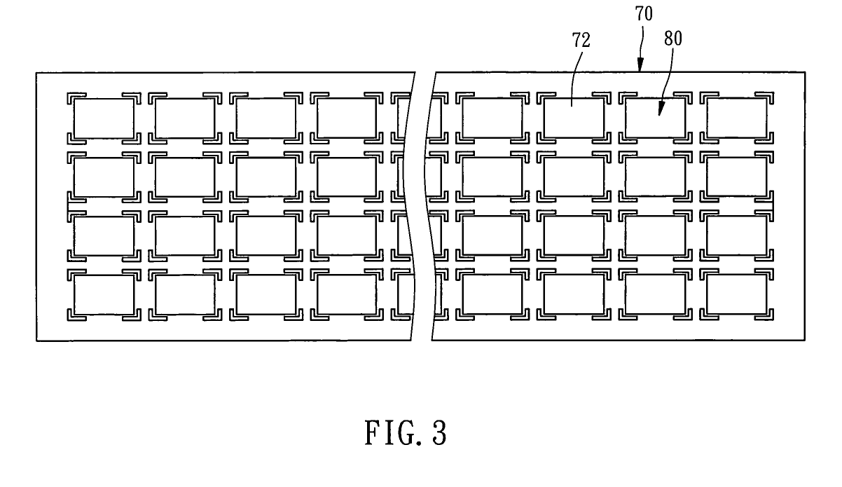

The IC package 10 is characterized in that a colored-pattern layer 60 is disposed on a surface 42 of the insulating cover layer 40 by an ink-based jet printing apparatus. The ink indicates a solution composed of pigment, binder, filler, or dye. As shown in FIG. 3, a plate-like holder 70 having a plurality of frames 72 is prepared and then a plurality of chip packages 80 having none of any colored patterns are arranged in the frames 72 one by one. Next, the plate-like holder 70 is placed on a working platform (not shown) of a jet printing machine, and then processed by the ink jet printing. Finally, the colored-pattern layer 60 is produced on the surface 42 of the insulating cover layer 40. In addition, it is to be noted that the present invention has though been described with respect to a specific preferred embodiment thereof, it is no way limited to the details of the illustrated structures but changes and modifications may be made within the scope of the appended claims. For example, the colored-pattern layer can be disposed on a film by the ink jet printing and then transferred to the surface of the insulating cover layer.

What is claimed is:

1. An IC package having a colored pattern, comprising:
a substrate;
a chip electrically connected with the substrate;
an insulating cover layer covering the chip; and
a colored-pattern layer disposed on a surface of the insulating cover layer.

2. The IC package as defined in claim 1, wherein the insulating cover layer comprises a top side; the colored-pattern layer is disposed on the top side of the insulating cover layer.

3. The IC package as defined in claim 1, wherein the colored-pattern layer is disposed by ink jet printing.

4. The IC package as defined in claim 1, wherein the colored-pattern layer is disposed on a film by ink jet printing and then transferred to the surface of the insulating cover layer.

5. The IC package as defined in claim 2, wherein the colored-pattern layer is disposed by ink jet printing.

6. The IC package as defined in claim 2, wherein the colored-pattern layer is disposed on a film by ink jet printing and then transferred to the surface of the insulating cover layer.
